(19) United States
(12) Patent Application Publication
(10) Pub. No.: US 2023/0253391 A1
(43) Pub. Date: Aug. 10, 2023

(54) HALF-BRIDGE MODULE WITH REVERSED DIODES

(71) Applicant: ZF Friedrichshafen AG, Friedrichshafen (DE)

(72) Inventor: Wei LIU, Friedrichshafen (DE)

(73) Assignee: ZF Friedrichshafen AG, Friedrichshafen (DE)

(21) Appl. No.: 18/165,198

(22) Filed: Feb. 6, 2023

(30) Foreign Application Priority Data
Feb. 7, 2022 (DE) 10 2022 201 215.1

(51) Int. Cl. H01L 25/18; H02M 7/00; H02M 7/5387; H01L 23/538

(52) U.S. Cl. CPC H01L 25/18; H02M 7/003; H02M 7/5387; H01L 23/5385; H01L 23/3735

(57) ABSTRACT

A half-bridge module includes a main substrate having at least one metallization layer, first and second semiconductor switches, first and second diodes, and an auxiliary substrate. The first and second semiconductor switches and diodes are arranged between the main and auxiliary substrates. The metallization layer is divided into DC+, AC, and DC− areas. The first semiconductor switch positive terminal is bonded to the DC+ area, the first diode anode side is bonded to the AC area. The second semiconductor switch positive terminal side is bonded to the AC area. The second diode anode side is bonded the to the DC− area. The first and second semiconductor switches negative terminal sides are bonded to the auxiliary substrate and the first and second diodes cathode sides are bonded to the auxiliary substrate, which interconnects the first and second semiconductor switches and diodes into a half-bridge.

### CROSS-REFERENCE TO RELATED APPLICATION

This application claims priority to German Application No. DE 10 2022 201 215.1, filed on Feb. 7, 2022, the entirety of which is hereby fully incorporated by reference herein.

### TECHNICAL FIELD

The present disclosure relates to a half-bridge module.

### BACKGROUND

In automotive applications with electrical drives, such as electrical cars and trucks, half-bridge modules are used for assembling inverters. Such inverters may generate the AC current, which is needed for driving an electrical motor, from a DC current, which may be provided by an electrical battery. In the moment, such half-bridge modules comprise Si semiconductors. However, due to their higher operation voltages and the possible higher switching frequencies, which may result in lower losses and a more efficient application of the half-bridge modules, it is also considered to use high bandgap semiconductors. Such power semiconductor modules based on high bandgap semiconductors may benefit from new module designs to reduce electromagnetic radiation and losses and to improve local cooling capabilities.

### SUMMARY

Therefore, it is an object of the present disclosure to provide a half-bridge module, which reduces the above-mentioned problems. This objective is achieved by the subject-matter disclosed herein. Advantageous embodiments are also disclosed herein.

The present disclosure relates to a half-bridge module. In general, the half-bridge module is a power semiconductor module, which is a device for mechanically and electrically interconnecting semiconductor chips. Here and in the following, the term “power” refers to devices and elements adapted for processing voltages of more than 100 V and/or more than 10 A. The semiconductor chips in the half-bridge module are interconnected to form a half-bridge, i.e. two semiconductor switch chips connected in series and a free-wheeling diode chip connected anti-parallel to each semiconductor switch chip.

According to an embodiment of the present disclosure, the half-bridge module comprises a main substrate comprising at least one metallization layer on an isolation layer. It is possible that a further metallization layer is provided on the isolation layer opposite to the (first) metallization layer.

The main substrate may be a DBC (direct bonded copper) substrate, i.e. one or two copper layers on a ceramics layer. The main substrate may be an (IMS) insulated metal substrate with an electrically isolating layer made of a polymer filled with ceramics particles. The one or more metallization layers may be made of metal, such as copper or aluminum. The electrically isolating layer may be made of plastics and/or ceramics.

According to an embodiment of the present disclosure, the half-bridge module comprises a first semiconductor switch chip and a second semiconductor switch chip. Each semiconductor switch chip comprises a positive terminal on a positive terminal side and a negative terminal on a negative terminal side opposite to the positive terminal side adapted for switching a current from the positive terminal to the negative terminal. Each semiconductor switch chip also may comprise a control terminal for controlling the resistance of the path between the positive and negative terminal.

Such semiconductor switch chips (as well as the diode chip described below) may have a plastics housing, which encloses a die made of a semiconductor material, which provides the functionality of the chip. The semiconductor switch chips may provide and/or may be transistors or thyristors. The positive terminal, negative terminal and control terminal may be provided as electrodes on the housing of the chip.

It may be that each of the semiconductor switch chips provides a bipolar transistor, in particular an N-channel bipolar transistor, for example an IGBT. In this case, the positive terminal is the collector, the negative terminal is the emitter and the control terminal is the base. It also may be that each of the semiconductor switch chips provides a field effect transistor, for example a MOSFET. In this case, the positive terminal is the drain, the negative terminal is the source and the control terminal is the gate.

As a further example, each of the semiconductor switch chips provides a thyristor. In this case, the positive terminal is the anode, the negative terminal is the cathode and the control terminal is the gate.

The semiconductor switch chips may be based on a wide bandgap semiconductor and/or the corresponding dies may be made of a wide bandgap material. For example, the semiconductor switch chips are based on GaN (gallium nitride) or SiC (silicon carbide). Such semiconductor switch chips allow for higher switching frequencies and/or higher operation voltages. However, it is also possible that the semiconductor switch chips are based on silicon alone.

According to an embodiment of the present disclosure, the half-bridge module comprises a first diode chip and a second diode chip, wherein each diode chip comprises an anode on an anode side and a cathode on a cathode side opposite to the anode side adapted for blocking a current from the cathode to the anode. In the case of a diode, the anode may be identified with a positive side and the cathode may be identified with a negative side.

The diode chips may be based on a wide bandgap semiconductor and/or the corresponding dies may be made of a wide bandgap material, such as mentioned above. In particular, the first and/or the second diode chip comprises a gallium oxide diode. A gallium oxide (for example a β-Ga2O3) diode has low losses and is adapted for processing high frequencies better than a silicon diode. The diode may be a Schottky barrier diode.

According to an embodiment of the present disclosure, the half-bridge module comprises an auxiliary substrate, wherein the first semiconductor switch chip, the second semiconductor switch chip, the first diode chip and the second diode chip are arranged between the main substrate and the auxiliary substrate. The auxiliary substrate may be a direct bonded copper substrate or a printed circuit board. In the case of a printed circuit board, the auxiliary substrate may have one or two metallization layers, which are separated by a plastics layer. Also, the main substrate may be a printed circuit board.

According to an embodiment of the present disclosure, the metallization layer of the main substrate is divided into a DC+ area, an AC area, and a DC− area, which are electrically separated from each other on the isolation layer. The first semiconductor switch chip is bonded with the positive terminal side to the DC+ area. The first diode chip is bonded with the anode side to the AC area. Also, the second semiconductor switch chip is bonded with the positive terminal side to the AC area. The second diode chip is bonded with the anode side to the DC− area. Furthermore, the first semiconductor switch chip and the second semiconductor switch chip are bonded with their negative terminal sides to the auxiliary substrate. The first diode chip and the second diode chip are bonded with their cathode sides to the auxiliary substrate. The auxiliary substrate is designed in such a way that it electrically interconnects the first semiconductor switch chip, the second semiconductor switch chip, the first diode chip and the second diode chip into a half-bridge. Here and in the following, bonding may refer to a process for electrically and mechanically connecting two metallic elements, such as soldering, welding and sintering.

The first semiconductor switch chip and the first diode chip are arranged in the same conduction direction side by side and are electrically interconnected anti-parallel by the two substrates (the main substrate and the auxiliary substrate). The same applies to the second semiconductor switch chip and the second diode chip.

The first semiconductor switch chip and the first diode chip are sandwiched between the two substrates, which have structured metallization layers and which are electrically interconnected to generate the anti-parallel connection of the two chips. In particular, there are separated metal patterns and/or areas between the first semiconductor switch chip and the first diode chip. The same applies to the second semiconductor switch chip and the second diode chip.

The first diode chip and the second diode chip are mounted with its anode side to the main substrate, which may have a heat sink on its opposite side, such that the anode side of the first diode chip is better cooled than the cathode side. Usually, the heat generating layer in a diode is located more on the anode side than on the cathode side.

This arrangement has the advantage that the anode sides of the diode chips are better cooled than the cathode sides. In particular for a gallium oxide diode and other wide bandgap materials, the thermal conduction is up to a factor of 1/10 worse than with silicon and most heating inside the diode takes place near the anode layer and/or anode side. The distance of the heating layer in the diode chips to the anode side may be about 2 u to 10 u, while the distance to the cathode side may be about 70 u to 500 u. So cooling the anode side results in a more effective heat transfer.

Assembling a complete half-bridge into one module has the advantages of a more compact design of the module and shorter current loops, which may reduce stray inductances.

According to an embodiment of the present disclosure, the first semiconductor switch chip and the first diode chip are arranged in a first row for the upper part of the half-bridge. The first row runs along a direction in parallel to the extension direction of the main substrate and the auxiliary substrate. Also, the second semiconductor switch chip and the second diode chip are arranged in a second row for the lower part of the half-bridge, which second row runs beside the first row and in an opposite direction to the first row. In such a way, the DC+ area and the DC− area can be arranged on one side of the half-bridge module. This allows a compact design of the half-bridge module.

According to an embodiment of the present disclosure, the DC+ area and the DC− area are arranged on a terminal side of the half-bridge module. There, also terminals for interconnecting the half-bridge module with further components can be connected. Terminals on the same side may result in smaller current loops and smaller stray inductances.

According to an embodiment of the present disclosure, the AC area is arranged on a further side of the half-bridge module opposite to the terminal side. The AC area may be arranged besides the DC+ area and the DC− area. The DC+ area, the DC− area and the AC area may form a pattern on the main substrate, where the DC+ area is in the upper left corner, the DC− area is in the lower left corner and the AC area occupies the upper and lower right corner.

According to an embodiment of the present disclosure, the AC area is L-shaped. A corner of the DC+ area may be surrounded by the AC area. The DC− area is arranged besides an arm of the L-shaped AC area. The DC+ area may be larger than the DC− area, since a semiconductor switch chip may occupy more areas than a diode chip. The AC area may have substantially the same area as the sum of the DC+ area and the DC− area. An L-shaped AC area may result in a compact design.

According to an embodiment of the present disclosure, the first semiconductor switch chip on the DC+ area, the first diode chip and the second semiconductor switch chip on the AC area, and the second diode chip on the DC− area are arranged in this order on a loop around a middle of the half-bridge module, such that a main current flows around this loop. In such a way, the main current loop through the half-bridge module may be reduced substantially to the interior of a housing of the half-bridge module and does not substantially depend on a design on the conductors connected to the half-bridge module.

According to an embodiment of the present disclosure, the auxiliary substrate comprises a first metallization layer, a second metallization layer and an isolation layer between them. As already mentioned, the auxiliary substrate may be a DBC or PCB.

According to an embodiment of the present disclosure, the first semiconductor switch chip, the second semiconductor switch chip, the first diode chip and the second diode chip are bonded to the first metallization layer and are electrically connected via the second metallization layer. The first metallization layer and the second metallization layer are structured and electrically connected with each other and with the metallization layer of the main substrate, such that together with the four chips, a half-bridge is formed.

According to an embodiment of the present disclosure, the first metallization layer is structured into a first area and a second area for an upper side of the half-bridge and a first area and a second area for a lower side of the half-bridge. Each of these areas may be arranged in a different corner of the half-bridge module. Each of these areas may be arranged above one of the four chips, i.e. the first semiconductor switch chip, the second semiconductor switch chip, the first diode chip and the second diode chip.

The first semiconductor switch chip is bonded with the negative terminal side to the first area for the upper side. The first diode chip is bonded with the cathode side to the second area for the upper side. The second semiconductor switch chip is bonded with the negative terminal side to the first area for the lower side. The second diode chip is bonded with the cathode side to the second area for the lower side. In such a way, the semiconductor switch chips and the diode chips are mounted in the same conducting direction into the half-bridge module. However, the first semiconductor switch chip and the first diode chip (as well as the second semiconductor switch chip and the second diode chip) are electrically connected anti-parallel and/or in reverse conduction direction to each other.

According to an embodiment of the present disclosure, the DC+ area is electrically connected with the second area for the upper side via a first post between the main substrate and the auxiliary substrate. Also, the AC area may be electrically connected with the second area for the lower side via a second post between the main substrate and the auxiliary substrate. Such electrically conducting posts may be provided by one or more pins provided by the auxiliary substrate in the form of a printed circuit board. Also, such posts may be bonded with each ends to the respective metallization layer.

According to an embodiment of the present disclosure, from a view in a direction orthogonal to the main substrate and the auxiliary substrate, the DC+ area and the second area for the upper side overlap each other. Also, from a view in a direction orthogonal to the main substrate and the auxiliary substrate, the AC area and the second area for the lower side overlap each other. Each of the main substrate and the auxiliary substrate defines a plane, which are substantially parallel to each other. The view direction is substantially orthogonal to these planes. In such a way, cylindrical pins and/or posts may be arranged between the main substrate and the auxiliary substrate to electrically connect the respective areas.

According to an embodiment of the present disclosure, the second metallization layer is structured into an upper side area and a lower side area. The term “structured” herein may refer to the fact that the respective areas are electrically separated from each other on the isolation layer to which they are attached.

The first area for the upper side of the first metallization layer is electrically connected to the upper side area of the second metallization layer. This may be done with through vias. The upper side area is electrically connected to the AC area via a third post between the main substrate and the auxiliary substrate. A through via may be an electrically conducting element that reaches through an isolation layer between the metallization layers. In particular, in the case of a printed circuit board, such through vias may be easily made. Again, such an electrically conducting post may be bonded to the respective metallization layers.

The same applies to the first area for the lower side: The first area for the lower side of the first metallization layer is electrically connected to the lower side area of the second metallization layer. This may be done with through vias. The lower side area is electrically connected to the DC− area via a fourth post between the main substrate and the auxiliary substrate.

According to an embodiment of the present disclosure, the half-bridge module further comprises a heat sink connected to the main substrate opposite to the first and second semiconductor switch chips and the first and second diode chips. The heat sink may be bonded or otherwise attached to a metallization layer of the main substrate opposite to the metallization layer to which the semiconductor switch chips and the diode chips are bonded. For example, the heat sink may be an air cooled heat sink or a liquid cooled heat sink.

These and other aspects of the present disclosure will be apparent from and elucidated with reference to the embodiments described hereinafter. Below, embodiments of the present disclosure are described in more detail with reference to the attached drawings.

### BRIEF DESCRIPTION OF THE DRAWINGS

FIG. 1 shows a circuit diagram of a half-bridge module according to an embodiment of the present disclosure.

FIG. 2 shows a schematic cross-sectional view of a half-bridge module according to an embodiment of the present disclosure.

FIG. 3 shows a schematic cross-sectional view of a power semiconductor module according to an embodiment of the present disclosure.

FIG. 4 shows a schematic cross-sectional view of a power semiconductor module according to a further embodiment of the present disclosure.

### DETAILED DESCRIPTION

The reference symbols used in the drawings, and their meanings, are listed in summary form in the list of reference symbols below. In principle, identical parts are provided with the same reference symbols in the figures.

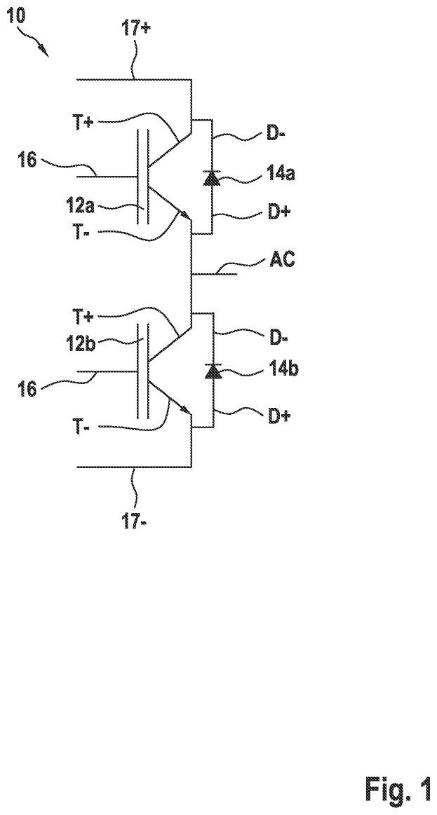

FIG. 1 shows a circuit diagram of a half-bridge module 10, which comprises two semiconductor switch chips 12a, 12b, which are electrically connected in series. A free-wheeling diode chip 14a, 14b is connected anti-parallel to each semiconductor switch chip 12a, 12b. Each semiconductor switch chip 12a, 12b comprises a positive terminal T+, a negative terminal T− and a control terminal 16. Each diode chip 14a, 14b comprises an anode D+ and a cathode D−.

The positive terminal T+ of the first semiconductor switch chip 12a and the cathode D− of the first diode chip 14a are connected with each other and are connected to a DC+ terminal 17+ of the half-bridge module 10. The negative terminal T− of the second semiconductor switch chip 12b and the anode D+ of the second diode chip 14b are connected with each other and are connected to a DC− terminal 17− of the half-bridge module 10.

The negative terminal T− of the first semiconductor switch chip 12a, the anode D+ of the first diode chip 14a, the positive terminal T+ of the second semiconductor switch chip 12b and the cathode D− of the second diode chip 14b are connected with each other and are connected to the AC terminal of the half-bridge module 10.

The diode chips 14a, 14b may provide a gallium oxide diode, in particular made of β-Ga2O3, and/or may be a Schottky barrier diode.

The semiconductor switch chips 12a, 12b may provide a bipolar transistor, such as an IGBT, a field effect transistor, such as a MOSFET, or a thyristor. Also, the semiconductor switch chips 12a, 12b may be made of a wide bandgap material.

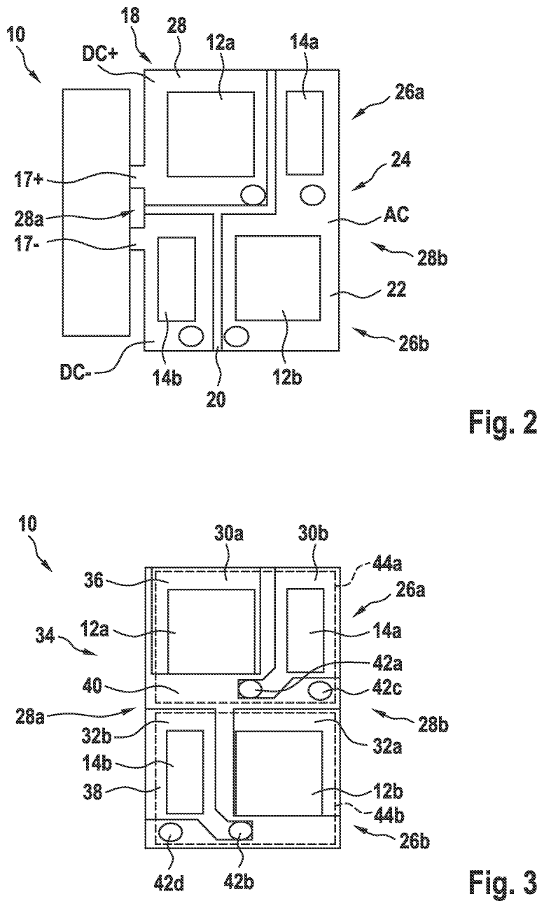

FIG. 2 shows a schematic cross-sectional view of a half-bridge module 10 along a first plane in parallel to the extension plane of a main substrate 18. FIG. 3 shows a schematic cross-sectional view of the half-bridge module 10 of FIG. 2 along a second plane above the first plane. FIG. 3 shows a schematic cross-sectional view of the half-bridge module 10 orthogonal the first and second plane and through the semiconductor switch chip 12a (or 12b) and the diode chip 14a (or 14b). Note that FIG. 3 can be seen as a cross-section through 12a and 14a or a cross-section through 12b and 14b in the opposite direction.

The semiconductor switch chips 12a, 12b and the diode chips 14a, 14b are bonded to a main substrate 18. The main substrate 18 is composed of an isolation layer 20, which is sandwiched between two metallization layers 22, 24 (see FIG. 3). The main substrate 18 may be a printed circuit board, an IMS (insulated metal substrate) or a DBC (direct bonded copper) substrate. It also may be that the main substrate 18 comprises more than three layers.

The semiconductor switch chips 12a, 12b and the diode chips 14a, 14b are bonded to the metallization layer 22. The metallization layer 22 is structured and is divided into a DC+ area (DC+), connected to the DC+ terminal 17+, an AC area (AC), and a DC− area (DC−), connected to the DC− terminal 17−. The semiconductor switch chip 12a is bonded to the DC+ area, the diode chip 14a and the semiconductor switch chip 12b are bonded to the AC area and the diode chip 14b is bonded to the DC− area.

The half-bridge module 10 is divided into two parts 26a, 26b. The upper or first part 26a provides an upper part of the-half-bridge and the lower or second part 26b provides a lower part of the-half-bridge. The first semiconductor switch chip 12a and the first diode chip 14a are arranged in a first row for the upper part 26a of the half-bridge. The second semiconductor switch chip 12b and the second diode chip 14b are arranged in a second row for the lower half 26b of the half-bridge, which second row runs beside the first row and in an opposite direction to the first row. Both rows are substantially parallel.

The DC+ area and the DC− area are arranged on a terminal side 28a of the half-bridge module 10. The AC area is arranged on a further, second side 28b of the half-bridge module 10 opposite to the terminal side 28a. The AC area AC is arranged besides the DC+ area and the DC− area, which are arranged in a direction substantially orthogonal to the first row and the second row. The AC area is L-shaped, wherein a corner of the DC+ area is surrounded by the AC area. The DC− area DC− is arranged besides an arm of the L-shaped AC area.

The first semiconductor switch chip 12a on the DC+ area, the first diode chip 14a and the second semiconductor switch chip 14b on the AC area, and the second diode chip 14b on the DC− area are arranged in this order on a loop around a middle of the half-bridge module 10, such that a main current flows around this loop. Such a main current flows from the DC+ terminal 17+ to the DC− terminal 17−.

As shown in FIG. 2, a capacitor 29 can be connected to the DC+ terminal 17+ and to the DC− terminal 17− on the terminal side 28a. Since both terminals 17+ and 17− are located on the same side 28a, a capacitor 29 with terminals on the same side can be used and/or the current loop, into which the capacitor 29 is included, can be designed smaller.

The half-bridge module 10 furthermore comprises an auxiliary substrate 34, which is composed of two metallization layers 36, 38 and an isolation layer 40 sandwiched between the metallization layers 36, 38. The auxiliary substrate 34 may be a DBC (direct bonded copper) substrate or a PCB (printed circuit board). The semiconductor switch chip 12, 12a, 12b and the diode chip 14, 14a, 14b are arranged between the main substrate 18 and the auxiliary substrate 34.

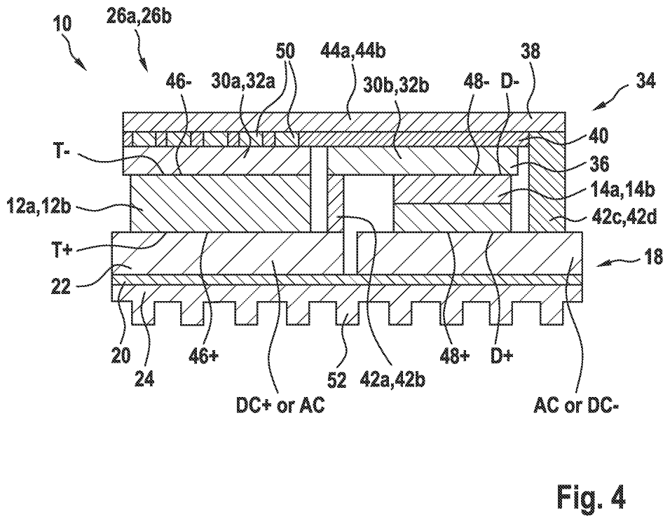

As shown in FIG. 4, the semiconductor switch chips 12, 12a, 12b comprise the positive terminal T+ on a positive terminal side 46+ and the negative terminal T− on a negative terminal side 46− opposite to the positive terminal side 46+. The diode chips 14a, 14b comprise the anode D+ on an anode side 48+ and the cathode D− on a cathode side 48− opposite to the anode side 48+.

The first semiconductor switch chip 12a, the second semiconductor switch chip 12b, the first diode chip 14a and the second diode chip 14b are bonded to the first metallization layer 36 and are electrically connected via the second metallization layer 38.

The first metallization layer 36 is structured into a first area 30a and a second area 30b for an upper side of the half-bridge and a first area 32a and a second area 32b for a lower side of the half-bridge. The first semiconductor switch chip 12a is bonded with the negative terminal side 46− to the first area 30a for the upper side. The first diode chip 14a is bonded with the cathode side 48− to the second area 30b for the upper side. The second semiconductor switch chip 12b is bonded with the negative terminal side 46− to the first area 32a for the lower side. The second diode chip 14b is bonded with the cathode side 48− to the second area 32b for the lower side.

Furthermore, the DC+ area is electrically connected with the second area 30b for the upper side via a first post 42a between the main substrate 18 and the auxiliary substrate 34. The AC area is electrically connected with the second area 32b for the lower side via a second post 42b between the main substrate 18 and the auxiliary substrate 34.

The second metallization layer 38 is structured into an upper side area 44a and a lower side area 44b. The first area 30a for the upper side of the first metallization layer 36 is electrically connected to the upper side area 44a of the second metallization layer 38, for example with through vias 50 through the isolation layer 40 of the auxiliary substrate 34. The upper side area 44a is electrically connected to the AC area AC via a third post 46c between the main substrate 18 and the auxiliary substrate 34.

The first area 32a for the lower side of the first metallization layer 36 is electrically connected to the lower side area 44b of the second metallization layer 38, for example with through vias 50 through the isolation layer 40 of the auxiliary substrate 34. The lower side area 44b is electrically connected to the DC− area DC− via a fourth post 46d between the main substrate 18 and the auxiliary substrate 34.

The DC+ area is electrically connected to the second area 30b of the upper part. The first area 30a of the upper part is electrically connected to the AC area. In such a way, the diode chip 14a (with respect to the anode side 48+ and the cathode side 48−) is arranged in parallel and/or in the same conduction direction as the semiconductor switch chip 12a (with respect to the positive terminal side 46+ and the negative terminal side 46−). This is beneficial in view of cooling. Furthermore, via the auxiliary substrate 34, the diode chip 14a is electrically connected anti-parallel to the semiconductor switch chip 12a.

Analogously, the AC area is electrically connected to the second area 32b of the lower part, and the first area 32a of the lower part is electrically connected to the DC−area. In such a way, the diode chip 14b (with respect to the anode side 48+ and the cathode side 48−) is arranged in parallel and/or in the same conduction direction as the semiconductor switch chip 12b (with respect to the positive terminal side 46+ and the negative terminal side 46−). This is beneficial in view of cooling. Furthermore, via the auxiliary substrate 34, the diode chip 14b is electrically connected anti-parallel to the semiconductor switch chip 12b.

In particular, when the diode chips 14a, 14b provide and/or are gallium oxide diodes and/or diodes made of other wide bandgap materials, the thermal conduction is worse than in silicon. Furthermore, most heating inside the diode chips 14a, 14b takes place near the anode layer and/or anode side 48+. The distance of the layer in the diode chips 14a, 14b, where most of the heat is generated, to the anode side 48+may be about 2 u to 10 u, while the distance to the cathode side 48− to this layer may be about 70 u to 500 u. So cooling the anode side 48+, which is directed towards a heat sink 52, results in a more effective heat transfer.

From a view in a direction orthogonal to the main substrate 18 and the auxiliary substrate 34, the second area 30b of the upper part and the DC+ area overlap each other. Also, the second area 32b of the lower part and the AC area overlap each other. To electrically connect these areas (30a with DC+ or 32a with AC), electrically conducting posts 42a, 42b are used, which are bonded to the respective areas.

The auxiliary substrate 34 may be a PCB and the posts 42a, 42b (as well as the posts 42c, 42d) may be pins that are soldered to the respective metallization layer 36, 38. When attaching the auxiliary substrate 34 to the rest of the half-bridge module 10, the pins and/or posts 42a, 42b, 42c, 42d may be soldered to the metallization layer 22.

FIG. 4 shows that a heat sink 52 is attached to the metallization layer 24 of the main substrate 18. The heat sink 32 may be bonded or otherwise attached to the back side of the main substrate 18 opposite to the semiconductor switch chips 12a, 12b and the diode chips 14a, 14b. The heat sink 52 may be any kind of cooling element and/or may be based on air and water cooling. Also active and passive cooling may be possible.

While the present disclosure has been illustrated and described in detail in the drawings and foregoing description, such illustration and description are to be considered illustrative or exemplary and not restrictive; the present disclosure is not limited to the disclosed embodiments. Other variations to the disclosed embodiments can be understood and effected by those skilled in the art and practicing the claimed present disclosure, from a study of the drawings, the disclosure, and the appended claims. In the claims, the word “comprising” does not exclude other elements or steps, and the indefinite article “a” or “an” does not exclude a plurality. A single processor or controller or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

### LIST OF REFERENCE SYMBOLS

10 half-bridge module
12a first semiconductor switch chip
12b second semiconductor switch chip
14a first diode chip
14b second diode chip
T+ positive terminal
T− negative terminal
16 control terminal
17+ DC+ terminal
17− DC− terminal
D+ anode
D− cathode
DC+ DC+ area
DC− DC− area
AC AC area
18 main substrate
20 isolation layer
22 first metallization layer
24 second metallization layer
26a upper/first part
26b lower/second part
28a first/terminal side
28b second/opposite side
29 capacitor
30a first area of upper part
30b second area of upper part
32a first area of lower part
32b second area of lower part
34 auxiliary substrate
36 first metallization layer
38 second metallization layer
40 isolation layer
42a first post
42b second post
42c third post
42d fourth post
44a upper side area
44b lower side area
46+ positive terminal side
46− negative terminal side
48+ anode side
48− cathode side
50 through via
52 heat sink

1. A half-bridge module, comprising:
a main substrate comprising at least one metallization layer on an isolation layer;
a first semiconductor switch chip and a second semiconductor switch chip, wherein each semiconductor switch chip comprises a positive terminal on a positive terminal side and a negative terminal on a negative terminal side opposite to the positive terminal side adapted for switching a current from the positive terminal to the negative terminal;
a first diode chip and a second diode chip, wherein each diode chip comprises an anode on an anode side and a cathode on a cathode side opposite to the anode side adapted for blocking a current from the cathode to the anode;
an auxiliary substrate, wherein the first semiconductor switch chip, the second semiconductor switch chip, the first diode chip and the second diode chip are arranged between the main substrate and the auxiliary substrate;
wherein the metallization layer of the main substrate is divided into a DC+ area, an AC area, and a DC− area, which are electrically separated from each other on the isolation layer;
wherein the first semiconductor switch chip is bonded with the positive terminal side to the DC+ area;
wherein the first diode chip is bonded with the anode side to the AC area;
wherein the second semiconductor switch chip is bonded with the positive terminal side to the AC area;
wherein the second diode chip is bonded with the anode side to the DC− area;
wherein the first semiconductor switch chip and the second semiconductor switch chip are bonded with their negative terminal sides to the auxiliary substrate, and the first diode chip and the second diode chip are bonded with their cathode sides to the auxiliary substrate, which interconnects the first semiconductor switch chip, the second semiconductor switch chip, the first diode chip, and the second diode chip into a half-bridge.

2. The half-bridge module of claim 1,
wherein the first semiconductor switch chip and the first diode chip are arranged in a first row for an upper part of the half-bridge;
wherein the second semiconductor switch chip and the second diode chip are arranged in a second row for a lower part of the half-bridge, which second row runs beside the first row and in an opposite direction to the first row.

3. The half-bridge module of claim 2,
wherein the first semiconductor switch chip on the DC+ area, the first diode chip and the second semiconductor switch chip on the AC area, and the second diode chip on the DC− area are arranged in this order on a loop around a middle of the half-bridge module, such that a main current flows around this loop.

4. The half-bridge module of claim 2, further comprising:
a heat sink connected to the main substrate opposite to the first and second semiconductor switch chips and the first and second diode chips.

5. The half-bridge module of claim 2,
wherein the DC+ area and the DC− area are arranged on a terminal side of the half-bridge module;
wherein the AC area is arranged on a further side of the half-bridge module opposite to the terminal side; and
wherein the AC area is arranged besides the DC+ area and the DC− area.

6. The half-bridge module of claim 5,
wherein the first semiconductor switch chip on the DC+ area, the first diode chip and the second semiconductor switch chip on the AC area, and the second diode chip on the DC− area are arranged in this order on a loop around a middle of the half-bridge module, such that a main current flows around this loop.

7. The half-bridge module of claim 5, further comprising:
a heat sink connected to the main substrate opposite to the first and second semiconductor switch chips and the first and second diode chips.

8. The half-bridge module of claim 1,
wherein the DC+ area and the DC− area are arranged on a terminal side of the half-bridge module;
wherein the AC area is arranged on a further side of the half-bridge module opposite to the terminal side; and
wherein the AC area is arranged besides the DC+ area and the DC− area.

9. The half-bridge module of claim 1,
wherein the AC area is L-shaped;
wherein a corner of the DC+ area is surrounded by the AC area; and
wherein the DC−area is arranged besides an arm of the L-shaped AC area.

10. The half-bridge module of claim 9,
wherein the first semiconductor switch chip on the DC+ area, the first diode chip and the second semiconductor switch chip on the AC area, and the second diode chip on the DC− area are arranged in this order on a loop around a middle of the half-bridge module, such that a main current flows around this loop.

11. The half-bridge module of claim 9, further comprising:
a heat sink connected to the main substrate opposite to the first and second semiconductor switch chips and the first and second diode chips.

12. The half-bridge module of claim 1,
wherein the first semiconductor switch chip on the DC+ area, the first diode chip and the second semiconductor switch chip on the AC area, and the second diode chip on the DC− area are arranged in this order on a loop around a middle of the half-bridge module, such that a main current flows around this loop.

13. The half-bridge module of claim 1,
wherein the auxiliary substrate comprises a first metallization layer, a second metallization layer, and an isolation layer between the first metallization layer and the second metallization layer;
wherein the first semiconductor switch chip, the second semiconductor switch chip, the first diode chip, and the second diode chip are bonded to the first metallization layer and are electrically connected via the second metallization layer.

14. The half-bridge module of claim 13,
wherein the first metallization layer is structured into a first area and a second area for an upper side of the half-bridge and a first area and a second area for a lower side of the half-bridge;
wherein the first semiconductor switch chip is bonded with the negative terminal side to the first area for the upper side;
wherein the first diode chip is bonded with the cathode side to the second area for the upper side;
wherein the second semiconductor switch chip is bonded with the negative terminal side to the first area for the lower side; and
wherein the second diode chip is bonded with the cathode side to the second area for the lower side.

15. The half-bridge module of claim 14,
wherein the DC+ area is electrically connected with the second area for the upper side via a first post between the main substrate and the auxiliary substrate; and
wherein the AC area is electrically connected with the second area for the lower side via a second post between the main substrate and the auxiliary substrate.

16. The half-bridge module of claim 14,
wherein the second metallization layer is structured into an upper side area and a lower side area;
wherein the first area for the upper side of the first metallization layer is electrically connected to the upper side area of the second metallization layer;
wherein the upper side area is electrically connected to the AC area via a third post between the main substrate and the auxiliary substrate;
wherein the first area for the lower side of the first metallization layer is electrically connected to the lower side area of the second metallization layer; and
wherein the lower side area is electrically connected to the DC− area via a fourth post between the main substrate and the auxiliary substrate.

17. The half-bridge module of claim 1, further comprising:
a heat sink connected to the main substrate opposite to the first and second semiconductor switch chips and the first and second diode chips.

18. The half-bridge module of claim 1,
wherein at least one of the first diode chip or the second diode chip comprises a gallium oxide diode.

19. The half-bridge module of claim 1,
wherein the main substrate is a direct bonded copper substrate or an insulated metal substrate.

20. The half-bridge module of claim 1,
wherein the auxiliary substrate is a direct bonded copper substrate or a printed circuit board.
